(19) United States
(12) Patent Application Publication
(10) Pub. No.: US 2007/0257293 A1
(43) Pub. Date: Nov. 8, 2007

(54) Semiconductor memory device and method for production of the semiconductor memory device

(76) Inventor: Josef Willer, Riemerling (DE)

Correspondence Address: SLATER & MATSIL LLP, 17950 PRESTON ROAD, SUITE 1000, DALLAS, TX, 75252, US

(21) Appl. No.: 11/429,929

(22) Filed: May 8, 2006

(51) Int. Cl. H01L 29/94; H01L 27/108; H01L 29/76; H01L 31/119

(52) U.S. Cl. 257/301

(57) ABSTRACT

The semiconductor memory device has a substrate with a main surface, on which parallel trenches are arranged. A memory layer is disposed at the sidewalls of the trenches, and gate electrodes are disposed in the trenches. Buried bitlines are formed as doped regions between neighboring trenches. The buried bitlines abut the sidewalls of the trenches and comprise upper surfaces, which are arranged at a specified distance from the bottom of the trenches. Source/drain regions are formed by sections of the buried bitlines.

### TECHNICAL FIELD

This invention concerns integrated semiconductor memory devices, especially charge-trapping memory devices.

### BACKGROUND

Semiconductor memory devices have an array of memory cells, which are arranged in such a fashion that they can be addressed via bitlines and wordlines using a logic circuitry. The addressing circuitry, which is usually realized as a CMOS logic circuit, is arranged in a peripheral area of the device surface. The CMOS components are transistors whose structures differ from the structure of the memory cell transistors. Nevertheless, it is important that the device including all the integrated transistor structures can be produced in the same manufacturing process. The device dimensions are shrunk to achieve a miniaturization from one chip generation to the next chip generation.

Non-volatile memory cells that are electrically programmable and erasable can be realized as charge-trapping memory cells comprising a memory layer sequence of dielectric materials. A memory layer that is suitable for charge-trapping is arranged between upper and lower boundary layers of dielectric material having a larger energy band gap than the memory layer. The memory layer sequence is arranged between a channel region within a semiconductor body and a gate electrode provided to control the channel by means of an applied electric voltage.

In the programming process, charge carriers in the channel region are induced to penetrate the lower boundary layer and are trapped in the memory layer. The trapped charge carriers change the threshold voltage of the cell transistor structure. Different programming states can be read by applying the appropriate reading voltages. Examples of charge-trapping memory cells are the SONOS memory cells, in which the boundary layers are oxide and the memory layer is a nitride of the semiconductor material, usually silicon.

The memory layer can be substituted with another dielectric material, provided the energy band gap is smaller than the energy band gap of the boundary layers. The difference in the energy band gaps should be as great as possible to secure a good charge carrier confinement and thus a good data retention. When using silicon dioxide as boundary layers, the memory layer may be tantalum oxide, hafnium oxide, titanium oxide, zirconium oxide or aluminum oxide. Also intrinsically conducting (non-doped) silicon may be used as the material of the memory layer.

### SUMMARY OF THE INVENTION

The semiconductor memory device has a substrate with a main surface, on which parallel trenches are arranged. A memory layer is disposed at the sidewalls of the trenches, and gate electrodes are disposed in the trenches. Buried bitlines are formed as doped regions between neighboring trenches. The buried bitlines abut the sidewalls of the trenches and comprise upper surfaces, which are arranged at a specified distance from the bottom of the trenches. Source/drain regions are formed by sections of the buried bitlines.

The method for production of the memory devices include the steps of providing a semiconductor substrate with a main surface and etching parallel trenches at a distance from one another into this surface. A memory layer sequence suitable for charge-trapping is applied at least to the sidewalls of the trenches. An electrically conductive material is applied into the trenches. An implantation of doping atoms into the main surface between the trenches is performed. Buried bitlines are formed, which comprise lower junctions above the bottoms of the trenches. Wordline stacks are arranged transversally to the buried bitlines. The electrically conductive material in the trenches is structured into gate electrodes.

These and other features of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a perspective cross-section of an embodiment of the semiconductor device;

FIG. 2 shows a cross-section of an intermediate product of the production method;

FIG. 3 shows a cross-section of an intermediate product after the application of a memory layer sequence;

FIG. 4 shows a cross-section according to FIG. 3 after the formation of gate electrodes and an encapsulation;

FIG. 5 shows a cross-section according to FIG. 4 after the formation of source/drain regions;

FIG. 6 shows a cross-section according to FIG. 5 for another embodiment;

FIG. 7 shows a cross-section according to FIG. 5 after an application of an insulating layer; and

FIG. 8 shows a cross-section according to FIG. 7 after the application of wordline layers.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In one embodiment, the semiconductor memory device has an arrangement of parallel trenches at a main surface of a substrate, a memory layer or, preferably, a memory layer sequence disposed at least at the sidewalls of the trenches, and gate electrodes disposed in the trenches. Buried bitlines, including source/drain regions, are formed as doped regions between neighboring trenches and abut the sidewalls of the trenches. The main substrate surface is located at a specified distance from the bottom of the trenches. Wordline stacks contacting the gate electrodes from above are arranged at the main surface of the substrate to connect rows of gate electrodes transversally to the buried bitlines. The wordline stacks are arranged at a distance from the upper surfaces of the source/drain regions.

In an embodiment, the buried bitlines can be provided with a metalization, which can be formed by a salicide (self-aligned silicide) or a metal silicide. In especially preferred embodiments, the memory layer is a dielectric material suitable for charge trapping.

A preferred embodiment method for production of semiconductor memory devices uses a semiconductor substrate with a main surface, in which parallel trenches are etched at a distance from one another. A memory layer sequence is applied at least to the sidewalls of the trenches. An electrically conductive material is filled into the trenches. Doping atoms are implanted into the main surface between the trenches to form buried bitlines having lower junctions above the bottoms of the trenches. Wordline stacks are arranged transversally to the buried bitlines, and the electrically conductive material in the trenches is structured into gate electrodes, preferably in a self-aligned manner with respect to the wordlines.

The memory layer sequence is preferably selected to be suitable for charge trapping. The electrically conductive material in the trenches can be formed from polysilicon and can be covered with an encapsulation, which is preferably formed of oxide. An electrically conductive layer can be applied onto the buried bitlines, preferably a metal silicide or a salicide.

A preferred variant of the method includes the process steps of providing a semiconductor substrate with a main surface, applying a gate dielectric on the main surface, applying a gate layer on the gate dielectric, applying a first hardmask on the gate layer, etching parallel trenches into an area of the main surface, applying a memory layer sequence, preferably of dielectric materials, at least to the sidewalls of the trenches, forming electrically conductive polysilicon in the trenches, forming an encapsulation of the polysilicon by oxide, applying a second hardmask that leaves the area of the main surface uncovered, removing the first hardmask and the gate layer in the area selectively to the second hardmask, performing an implantation of doping atoms, removing the second hardmask selectively to the first hardmask, applying an electrically insulating layer, uncovering the polysilicon in the trenches, and removing the first hardmask.

The first hardmask is preferably formed to cover an addressing periphery. It can be nitride. The second hardmask can be carbon. The memory layer sequence is preferably applied including at least one dielectric material suitable for charge trapping.

It is especially advantageous to apply a layer sequence that is provided for the gate electrodes and conductors of a peripheral circuit also as a mask in the region of the memory cell array. This enables to keep the surface of the device planar throughout the processing and thus to reduce manufacturing tolerances in obtaining a specified location of the lower source/drain junctions.

FIG. 1 shows a perspective cross-section of an embodiment of the semiconductor memory device. A substrate 1 of semiconductor material is provided with a doped well 2 of opposite type of conductivity. The substrate surface is provided with parallel trenches having sidewalls and bottoms. A memory layer sequence is applied to the inner surfaces of the trenches and comprises a lower boundary layer 3, a memory layer 4, and an upper boundary layer 5. The memory layer 4 can especially be a dielectric material that is suitable for charge trapping. If the memory layer 4 is nitride, for example, the lower boundary layer 3 and the upper boundary layer 5 can be oxide. The memory layer 4 need not occupy the whole trench bottoms. It suffices if the memory layer 4 is present at the channel ends where the storage takes place. A gate electrode 6 is arranged in the trenches for every memory cell separately. Source/drain regions 7 are formed as doped regions at a specified depth below the substrate surface 8 and preferably as sections of buried bitlines formed by striplike doped regions. The channels of the transistor structures are located at the bottom of the trenches between the lower junctions 12 of the source/drain regions 7. The substrate surface 8 carries an interlayer 9, which can be oxide, for example. The interlayer 9 can be substituted with a metalization, which is provided to reduce the resistance of the buried bitlines. An insulating layer 10 is arranged above the interlayer 9 or metalization between the gate electrodes located in neighboring trenches. Wordline stacks 11 are formed, in this example, by a first wordline layer 11a, a second wordline layer 11b, and a wordline insulation 11c.

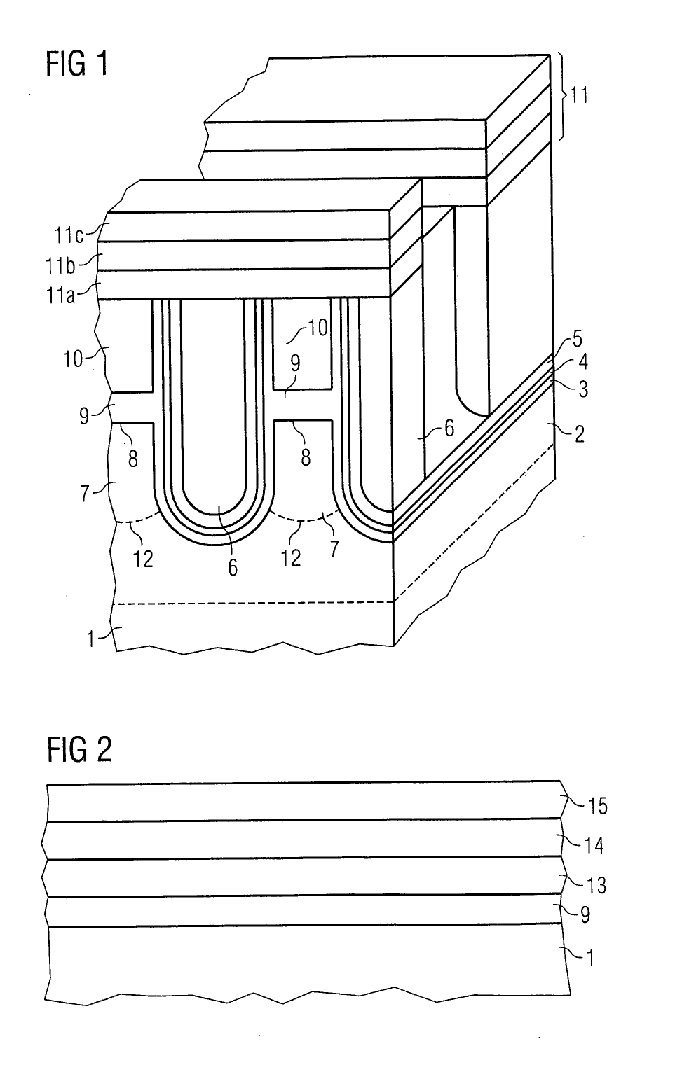

FIG. 2 shows a cross-section of an intermediate product of the production method. The substrate 1 can be provided with a well implant not shown in FIG. 2. The interlayer 9 of dielectric material, which can be provided as gate dielectric for transistor structures of a peripheral circuit, is formed on the substrate surface. A gate layer 13, for example amorphous silicon, is applied on the interlayer 9. A first hardmask 14 is preferably formed of nitride. FIG. 2 additionally shows the layer of a second hardmask 15, which is applied in further process steps.

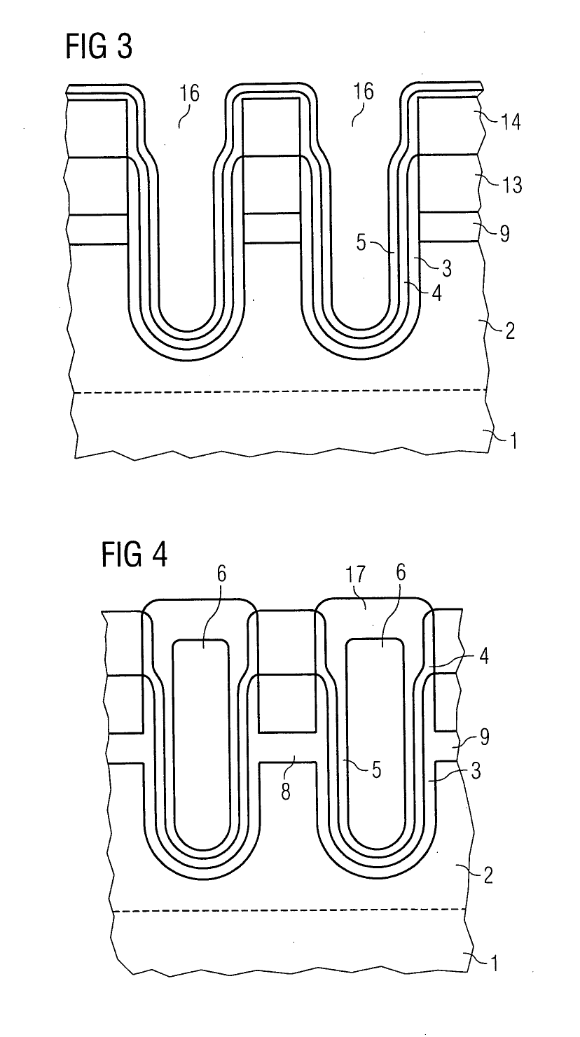

As shown in FIG. 3, the first hardmask 14 is used to etch parallel trenches 16 into the gate layer 13, the interlayer 9, and the substrate 1. The trenches are preferably etched by RIE (reactive ion etching). A sacrificial oxide can then be grown and removed in order to improve the semiconductor surface. A memory layer sequence is preferably applied as an oxide-nitride-oxide layer sequence or any other layer sequence of dielectric materials that is suitable for charge trapping. To this purpose, a bottom oxide forming the lower boundary layer 3 can be grown typically about 3 nm to 4 nm thick. The memory layer 4 can then be deposited by LPCVD (low-pressure chemical vapor deposition) as a nitride layer having a typical thickness of about 6 nm. The memory layer 4 can subsequently be removed from sections of the channels. The upper boundary layer 5 can be formed as a high-temperature oxide, followed by a wet anneal.

As shown in FIG. 4, gate electrodes 6, for example amorphous silicon, which may be doped, in particular to have p⁺conductivity, are formed in the trenches. The silicon is annealed, and the surface is planarized by chemical mechanical polishing. An encapsulation 17 is then formed to insulate the gate electrodes 6. The encapsulation 17 can be formed by a growth of thermal oxide. Instead, a recess can be etched into the silicon and an oxide can be deposited by CVD (chemical vapor deposition) in order to obtain a thicker oxide layer. The second hardmask 15 is then applied to cover the surface of the substrate except for an opening in the area of the memory cell array. The second hardmask 15 can be a carbon hardmask. The first hardmask 14 and the gate layer 13 are removed in the gaps between neighboring gate electrodes 6 of the memory cells, where the interlayer 9 is laid bare.

FIG. 5 shows the structure that is obtained in this way. The buried bitlines including the source/drain regions 7 are then formed by an implantation of a dopant. The junctions 12 of the source/drain regions 7 are indicated in FIG. 5 with broken lines. The junctions 12 are preferably located at lower sections of the sidewalls of the trenches, just above the curvature of the bottoms or already at the outer regions of the curvature. Further process steps may cause a diffusion of the dopant deeper into the substrate, so that the junctions 12 reach the position that is typically shown in FIG. 1, where the lower source/drain junctions 12 are located at the curvature of the trench bottoms. The type of conductivity of the source/drain regions 7 can be n+, if the well 2 is doped for p-conductivity. The interlayer 9 can remain on the surface of the semiconductor substrate or can be removed before the implantation.

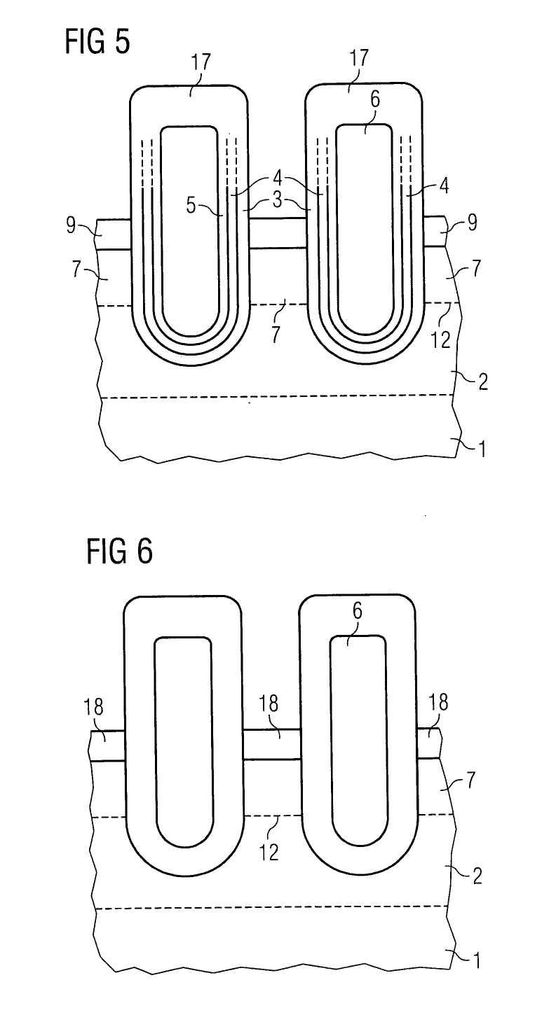

FIG. 6 shows another embodiment, in which the interlayer 9 is substituted with a metalization 18, which is provided to reduce the resistance of the buried bitlines. The metalization 18 can be formed by a salicide (self-aligned silicide) process. Instead, silicide can be deposited, planarized and etched back to the desired layer thickness.

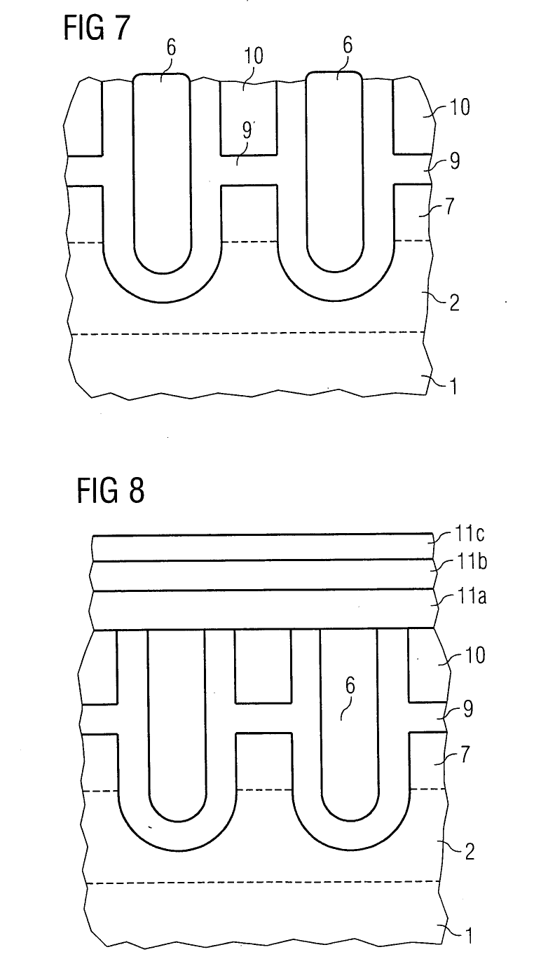

As shown in FIG. 7, an insulating layer 10 is applied between the gate electrodes 6. The insulating layer 10 can be a deposited CVD oxide. The insulating layer 10 and the encapsulation 17 are etched back until the upper surfaces of the gate electrodes 6 are uncovered. The hardmasks 14, 15 are removed. If the first hardmask 14 is nitride, it can be removed selectively with respect to the oxide of the insulating layer 10 and the encapsulation 17. After a planarization of the surface, the layers that are provided for the wordlines can be applied.

FIG. 8 shows an example with a wordline layer sequence encompassing a first wordline layer 11a, which may be polysilicon, for example. A second wordline layer 11b can be formed of a metal like tungsten or WN. The wordline stack is insulated above by a wordline insulation 11c, for example a nitride. The wordline stack is structured, and in the course of the structuring process, the material of the gate electrodes is separated into the gate electrodes 6 of the individual memory cells. In this way, the gate electrode is etched in a manner that is self-aligned to the wordlines. Thus the structure shown in FIG. 1 is obtained.

Concepts of this invention can be applied to contactless array types of a source/drain pitch of typically 120 nm and a wordline pitch of typically 2 F. A geometrical channel length of more than 80 nm is obtained. The preferred embodiment of this invention focuses on the integration of a multibit charge-trapping array, which makes use of the gate oxide, gate polysilicon and hardmask layers of the addressing periphery as mask layers. Both the channel recess and the junction implants have specified dimensions, which are defined from the same common substrate surface. In this way, possible channel length variations are minimized. The masks that are used in the production of the array of memory cells serve as a protective layer of the periphery. The oxidation step to form the encapsulation allows to remove the mask layers selectively to the structures of the memory cell array. A self-aligned formation of the source/drain junctions and a halo implant can be included in the process steps after the deposition of the gate electrode and the memory layer sequence.

Although the present invention and its advantages have been described in detail, it should be understood that various changes, substitutions and alterations can be made herein without departing from the spirit and scope of the invention as defined by the appended claims.

What is claimed is:

1. A semiconductor memory device, comprising:
a substrate comprising a main surface;
an arrangement of parallel trenches at the main surface, the trenches comprising sidewalls and bottoms;
a memory layer disposed at the sidewalls;
gate electrodes disposed in the trenches;
buried bitlines formed as doped regions between neighboring trenches, the buried bitlines abutting the sidewalls of the trenches and comprising upper surfaces, the upper surfaces being spaced from the bottoms of the trenches; and
source/drain regions being formed by sections of the buried bitlines.

2. The semiconductor memory device according to claim 1, further comprising wordline stacks arranged at the main surface of the substrate, the wordline stacks each coupling rows of gate electrodes transversally to the buried bitlines and contacting the gate electrodes from above, wherein the wordline stacks are arranged at a distance from the upper surfaces of the source/drain regions.

3. The semiconductor memory device according to claim 1, wherein the buried bitlines include a metalization.

4. The semiconductor memory device according to claim 1, wherein the buried bitlines include a layer of silicide.

5. The semiconductor memory device according to claim 1, wherein:
the bottoms of the trenches comprise a curvature;
the source/drain regions comprise lower junctions; and
the lower junctions abut the trenches at the curvature.

6. A semiconductor memory device comprising:
a substrate comprising a main surface;
an arrangement of parallel trenches at the main surface, the trenches comprising sidewalls and bottoms;
a memory layer disposed at the sidewalls;
gate electrodes disposed in the trenches;
buried bitlines formed as doped regions between neighboring trenches, the buried bitlines comprising upper surfaces, the buried bitlines being provided with electrically conductive layers on said upper surfaces; and
source/drain regions being formed by sections of the buried bitlines.

7. The semiconductor memory device according to claim 6, wherein:
the bottoms of the trenches comprise a curvature;
the source/drain regions comprise lower junctions; and
the lower junctions abut the trenches at the curvature.

8. The semiconductor memory device according to claim 6, further comprising:
wordline stacks arranged at the main surface of the substrate; and
the wordline stacks each connecting rows of gate electrodes transversally to the buried bitlines and contacting the gate electrodes from above;
wherein the wordline stacks are arranged at a distance from the upper surfaces of the source/drain regions.

9. The semiconductor memory device according to claim 6, wherein the electrically conductive layers on the upper surfaces of the buried bitlines are formed of a metal salicide.

10. The semiconductor memory device according to claim 6, wherein the electrically conductive layers on the upper surfaces of the buried bitlines are formed of a metal silicide.

11. A semiconductor memory device comprising:
a substrate comprising a main surface;
an arrangement of parallel trenches at the main surface;
gate electrodes disposed in the trenches;
source/drain regions disposed between neighboring trenches; and
means for charge trapping disposed between the gate electrodes and the source/drain regions.

12. The semiconductor memory device according to claim 11, further comprising buried bitlines arranged between neighboring trenches, sections of the buried bitlines forming the source/drain regions.

13. The semiconductor memory device according to claim 12, wherein the buried bitlines each have an upper surface with an electrically conductive layer arranged thereon.

14. The semiconductor memory device according to claim 13, wherein the electrically conductive layer comprises a metal silicide.

15. A method for producing a semiconductor memory device, the method comprising:
providing a semiconductor substrate;
etching parallel trenches at a distance from one another into a main surface of the semiconductor substrate, the trenches comprising sidewalls and bottoms;
applying a memory layer sequence suitable for charge trapping at least to the sidewalls;
forming an electrically conductive material in the trenches;
implanting dopants into the main surface between the trenches;
forming buried bitlines comprising lower junctions above the bottoms of the trenches;
arranging wordline stacks transversally to the buried bitlines; and
structuring the electrically conductive material in the trenches into gate electrodes.

16. The method according to claim 15, wherein forming the electrically conductive material in the trenches comprises depositing polysilicon.

17. The method according to claim 16, further comprising encapsulating the polysilicon with an oxide.

18. The method according to claim 15, further comprising forming an electrically conductive layer at a surface of the buried bitlines.

19. The method according to claim 18, wherein the electrically conductive layer comprises a metal silicide.

20. A method for producing a semiconductor memory device, the method comprising:
providing a semiconductor substrate;
applying an interlayer provided as a gate dielectric over a main surface of the semiconductor substrate;
applying a gate layer over the interlayer;
applying a first hardmask over the gate layer;
etching parallel trenches into an area of the main surface, the trenches comprising sidewalls and bottoms;
applying a memory layer sequence at least to the sidewalls;
forming electrically conductive polysilicon in the trenches;
forming an encapsulation of the polysilicon by oxide;
applying a second hardmask that leaves the area of the main surface uncovered;
removing the first hardmask and the gate layer in the area selectively to the second hardmask;
performing an implantation of doping atoms;
removing the second hardmask selectively to the first hardmask;
applying an electrically insulating layer;
uncovering the polysilicon in the trenches; and
removing the first hardmask.

21. The method according to claim 20, further comprising:
applying wordline stacks across the trenches, the wordline stacks connecting rows of gate electrodes; and
structuring the electrically conductive polysilicon in the trenches into gate electrodes.

22. The method according to claim 20, wherein the first hardmask is formed to cover an addressing periphery.

23. The method according to claim 20, wherein
the first hardmask comprises nitride; and
the second hardmask comprises carbon.

24. The method according to claim 20, wherein the memory layer sequence comprises at least one dielectric material suitable for charge trapping.
